(19) United States
(12) Patent Application Publication
(10) Pub. No.: US 2026/0360675 A1
(43) Pub. Date: Nov. 12, 2026

(54) SUBSTRATE PROCESSING APPARATUS AND ELECTROSTATIC CHUCK

(71) Applicant: Tokyo Electron Limited, Tokyo (JP)

(72) Inventors: Kohei OTSUKI, Miyagi (JP); Shin YAMAGUCHI, Miyagi (JP); Takashi KANAZAWA, Miyagi (JP)

(73) Assignee: Tokyo Electron Limited, Tokyo (JP)

(21) Appl. No.: 19/712,816

(22) Filed: Jun. 18, 2026

Related U.S. Application Data
(63) Continuation of application No. PCT/JP2024/044380, filed on Dec. 16, 2024.

(30) Foreign Application Priority Data
Dec. 26, 2023 (JP) 2023-218953

(51) Int. Cl. H01J 37/32; H10P 72/72

(52) U.S. Cl. CPC H01J 37/32715; H01J 37/32449; H10P 72/722; H01J 2237/2007; H01J 2237/3343

(57) ABSTRACT

A substrate processing apparatus includes a chamber, a substrate support in the chamber and having at least one first gas supply path and at least one second gas supply path, the substrate support including a base and an electrostatic chuck that has an upper surface, protrusions, a first annular groove, a second annular groove surrounding the first annular groove, and an annular projection disposed between the first annular groove and the second annular groove, protruding from the upper surface, and lower than the protrusions, being located on the upper surface, the first annular groove communicates with the at least one first gas supply path via at least one first gas supply hole, and the second annular groove communicates with the at least one second gas supply path via at least one second gas supply hole.

### CROSS-REFERENCE TO RELATED APPLICATIONS

This application is a bypass continuation application of International Application No. PCT/JP2024/044380 having an international filing date of Dec. 16, 2024 and designating the United States, the International Application being based upon and claiming the benefit of priority from Japanese Patent Application No. 2023-218953, filed on Dec. 26, 2023, the entire contents of each of which are incorporated herein by reference.

### BACKGROUND

### Field

The present disclosure relates to a substrate processing apparatus and an electrostatic chuck.

### Description of Related Art

JP2020-512692A discloses that an electrostatic chuck includes sealing bands located on a surface of the chuck. The sealing bands are in contact with a substrate to form a seal between adjacent cooling zones.

JP2006-257495A discloses that an outer peripheral ring that annularly surrounds an outermost periphery of a substrate holding surface of an electrostatic chuck is provided. The outer peripheral ring comes into contact with a substrate when the substrate is placed on the substrate holding surface.

### SUMMARY

According to the technique of the present disclosure, a temperature of a substrate is appropriately controlled to improve the uniformity of plasma processing in a substrate surface.

A substrate processing apparatus according to one aspect of the present disclosure includes: a substrate processing chamber, a substrate support disposed in the substrate processing chamber and having at least one first gas supply path and at least one second gas supply path, the substrate support including a base and an electrostatic chuck that is disposed on the base and has an upper surface, protrusions, a first annular groove, a second annular groove surrounding the first annular groove, and an annular projection disposed between the first annular groove and the second annular groove, protruding from the upper surface, and lower than the protrusions, being located on the upper surface, the first annular groove communicates with the at least one first gas supply path via at least one first gas supply hole, and the second annular groove communicates with the at least one second gas supply path via at least one second gas supply hole, at least one first control valve to control a flow rate or a pressure of a gas supplied via the at least one first gas supply path, and at least one second control valve to control a flow rate or a pressure of a gas supplied via the at least one second gas supply path.

### BRIEF DESCRIPTION OF DRAWINGS

The scope of the present disclosure is best understood from the following detailed description of exemplary embodiments when read in conjunction with the accompanying drawings.

FIG. 1 is a diagram schematically illustrating a configuration of a plasma processing system.

FIG. 2 is a vertical sectional view illustrating a schematic configuration of a plasma processing apparatus.

FIG. 3 is a plan view illustrating a schematic configuration of an electrostatic chuck according to a first embodiment.

FIG. 4 is a vertical sectional view illustrating the schematic configuration of the electrostatic chuck according to the first embodiment.

FIG. 5 is a sectional perspective view illustrating the schematic configuration of the electrostatic chuck according to the first embodiment and is a view illustrating a pressure distribution in a heat transfer space.

FIG. 6 is a plan view illustrating a schematic configuration of a portion of the electrostatic chuck according to the first embodiment.

FIG. 7 is a plan view illustrating a schematic configuration of a portion of the electrostatic chuck according to the first embodiment.

FIG. 8 is a graph illustrating results of a simulation performed in the first embodiment.

FIG. 9 is a graph illustrating results of a simulation performed in the first embodiment.

FIG. 10 is a graph illustrating results of a simulation performed in the first embodiment.

FIG. 11 is a sectional perspective view illustrating a schematic configuration of the electrostatic chuck according to a modification of the first embodiment.

FIG. 12 is a plan view illustrating a schematic configuration of a portion of the electrostatic chuck according to a modification of the first embodiment.

FIG. 13 is a plan view illustrating a schematic configuration of a portion of an electrostatic chuck according to a second embodiment.

FIG. 14 is a graph illustrating results of a simulation performed in the second embodiment.

FIG. 15 is a plan view illustrating a schematic configuration of a portion of an electrostatic chuck according to a third embodiment.

FIG. 16 is a sectional perspective view illustrating a schematic configuration of the electrostatic chuck according to the third embodiment and is a view illustrating a pressure distribution in a heat transfer space.

FIG. 17 is a plan view illustrating a schematic configuration of a portion of an electrostatic chuck according to a fourth embodiment.

FIG. 18 is a vertical sectional view illustrating a schematic configuration of an annular projection according to a sixth embodiment.

FIG. 19 is a vertical sectional view illustrating a schematic configuration of the annular projection according to the sixth embodiment.

FIG. 20 is a plan view illustrating a schematic configuration of the annular projection according to the sixth embodiment.

FIG. 21 is a plan view illustrating a schematic configuration of the annular projection according to the sixth embodiment.

### DETAILED DESCRIPTION

In a production step of a semiconductor device, for example, a semiconductor substrate (hereinafter referred to as a “substrate”) is subjected to plasma processing in a plasma processing apparatus. In the plasma processing apparatus, a processing gas is excited in a chamber to generate a plasma, and the substrate supported by an electrostatic chuck is processed by the plasma.

In plasma processing, it is preferred to appropriately control the temperature of the substrate to be processed to improve in-plane uniformity of the plasma processing on the substrate. Therefore, for example, a heat transfer gas such as a helium gas is supplied to a space between a rear surface of the substrate and a surface of the electrostatic chuck, and the temperature of the substrate is controlled by controlling the pressure of the heat transfer gas.

In recent years, to meet the demands for even higher precision in controlling the temperature of the substrate, the space between the rear surface of the substrate and the surface of the electrostatic chuck is partitioned into regions, and a pressure difference in the heat transfer gas is provided between the regions, thereby controlling the temperature of the substrate for each region. In the related art, to control the pressure of the heat transfer gas for each region, for example, a partition referred to as a so-called seal band, which is in direct contact with the rear surface of the substrate, is provided on the surface of the electrostatic chuck. For example, JP2020-512692A discloses a configuration in which the sealing bands are provided as the seal bands on the surface of the electrostatic chuck. JP2006-257495A described above discloses that an inner peripheral ring may be provided inside the outermost peripheral ring on the surface of the electrostatic chuck.

However, since the seal band is in direct contact with the rear surface of the substrate, the contact portion becomes a local temperature singularity. Specifically, the heat is transferred to the substrate in the contact portion, and the temperature of the substrate in the contact portion is reduced. The temperature singularity of the substrate affects the rate of the plasma processing, and as a result, the plasma processing may not be uniformly performed in the substrate surface. Therefore, the plasma processing in the related art has room for improvement.

The technique according to the present disclosure has been made in consideration of the circumstances described above, and controls the temperature of the substrate appropriately to improve the uniformity of the plasma processing in the substrate surface. Hereinafter, the plasma processing apparatus and the electrostatic chuck according to the present embodiment will be described with reference to the drawings. The same reference numerals will be given to elements having substantially the same functional configurations throughout the specification and the drawings, and redundant description thereof will be omitted.

### Plasma Processing System

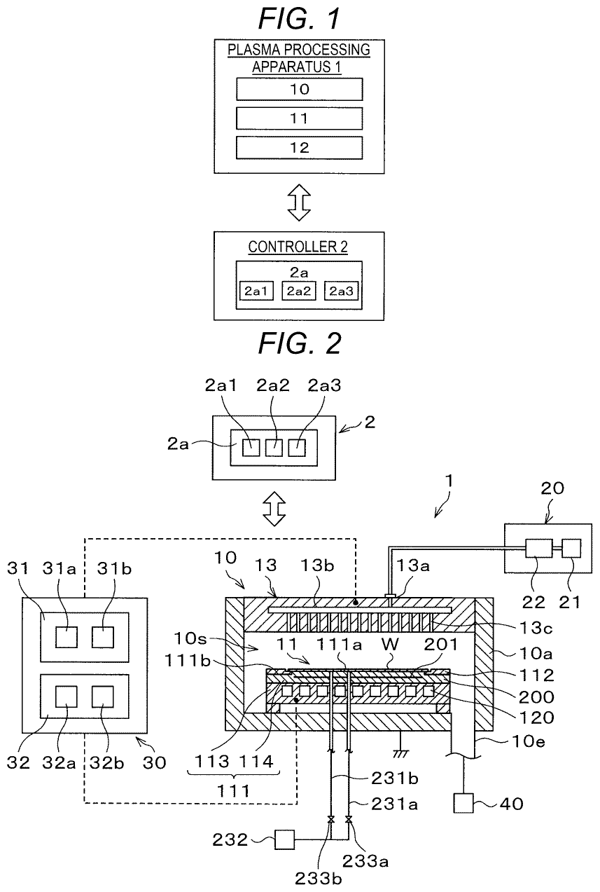

First, a plasma processing system according to an embodiment will be described. FIG. 1 is a diagram illustrating an example of a configuration of a plasma processing system.

In one embodiment, the plasma processing system includes a plasma processing apparatus 1 and a controller 2 (herein “controller” means the same as “controller circuitry”). The plasma processing system is an example of a substrate processing system, and the plasma processing apparatus 1 is an example of a substrate processing apparatus. The plasma processing apparatus 1 includes a plasma processing chamber 10 as a substrate processing chamber, a substrate support 11, and a plasma generator 12. The plasma processing chamber 10 has a plasma processing space. The plasma processing chamber 10 has at least one gas supply port via which at least one processing gas is supplied into the plasma processing space, and at least one gas exhaust port via which the gas is exhausted from the plasma processing space. The gas supply port is connected to a gas supply 20, which will be described later, and the gas exhaust port is connected to an exhaust system 40, which will be described later. The substrate support 11 is disposed in the plasma processing space and has a substrate support surface for supporting a substrate.

The plasma generator 12 is configured to generate plasma from at least one processing gas supplied into the plasma processing space. The plasma formed in the plasma processing space may be Capacitively Coupled Plasma (CCP), Inductively Coupled Plasma (ICP), Electron-Cyclotron-Resonance Plasma (ECR plasma), Helicon Wave Plasma (HWP), Surface Wave Plasma (SWP), or the like. Further, various types of plasma generators, including an alternating current (AC) plasma generator and a direct current (DC) plasma generator, may be used. In one embodiment, an AC signal (AC power) used by the AC plasma generator has a frequency in a range of 100 kHz to 10 GHz. Accordingly, the AC signal includes a radio frequency (RF) signal and a microwave signal. In one embodiment, the RF signal has a frequency in a range of 100 kHz to 150 MHz.

The controller 2 processes computer-executable instructions for instructing the plasma processing apparatus 1 to execute various steps described herein below. The controller 2 may be configured to control elements of the plasma processing apparatus 1 to execute the various steps described herein below. In one embodiment, part or all of the controller 2 may be in the plasma processing apparatus 1. The controller 2 may include a processor 2a1, a storage 2a2, and a communication interface 2a3. The controller 2 is implemented, for example, by a computer 2a. The processor 2a1 may be configured to read a program from the storage 2a2 and perform various control operations by executing the read program. The program may be stored in advance in the storage 2a2, or may be acquired via a medium when necessary. The acquired program is stored in the storage 2a2, read from the storage 2a2 by the processor 2a1, and executed thereby. The medium may be any of various recording media readable by the computer 2a, or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN). The controller/controller circuitry 2 can be programmable circuitry (e.g., embedded processor) or fixed circuitry (e.g., ASIC or PAL). In an exemplary embodiment, the controller/controller circuitry 2 can include one or more programmable processors/controllers.

### <plasma Processing Apparatus>

Hereinafter, a configuration example of a capacitively-coupled plasma processing apparatus as an example of the plasma processing apparatus 1 will be described. FIG. 2 is a diagram illustrating the example of the configuration of the capacitively-coupled plasma processing apparatus.

The capacitively-coupled plasma processing apparatus 1 includes the plasma processing chamber 10, the gas supply 20, a power source 30, and the exhaust system 40. The plasma processing apparatus 1 further includes the substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 constitutes at least a portion of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a support main body 111 and a ring assembly 112. An upper surface of the support main body 111 has a substrate support surface 111a that is a central region for supporting a substrate W and a ring support surface 111b that is an annular region for supporting the ring assembly 112. A wafer is an example of the substrate W. The ring support surface 111b of the support main body 111 surrounds the substrate support surface 111a of the support main body 111 in a plan view. The substrate W is disposed on the substrate support surface 111a of the support main body 111, and the ring assembly 112 is disposed on the ring support surface 111b of the support main body 111 to surround the substrate W on the substrate support surface 111a of the support main body 111.

In one embodiment, the support main body 111 includes a base 113 and an electrostatic chuck 114. The base 113 includes a conductive member. The conductive member of the base 113 may function as a lower electrode. The electrostatic chuck 114 is disposed on the base 113. The electrostatic chuck 114 includes a chuck main body 200 and an electrostatic electrode 201 disposed in the chuck main body 200. The chuck main body 200 has the substrate support surface 111a. In one embodiment, the chuck main body 200 also has the ring support surface 111b. Other members that surround the electrostatic chuck 114, such as an annular electrostatic chuck or an annular insulating member, may have the ring support surface 111b. In this case, the ring assembly 112 may be disposed on the annular electrostatic chuck or the annular insulating member, or may be disposed on both the electrostatic chuck 114 and the annular insulating member. At least one RF/DC electrode coupled to an RF power source 31 and/or a DC power source 32, which will be described late, may be disposed in the chuck main body 200. In this case, at least one RF/DC electrode functions as the lower electrode. When a bias RF signal and/or DC signal, which will be described later, is supplied to at least one RF/DC electrode, the RF/DC electrode is also referred to as a bias electrode. The conductive member of the base 113 and at least one RF/DC electrode may function as lower electrodes. The electrostatic electrode 201 may function as the lower electrode. The substrate support 11 therefore includes at least one lower electrode.

The ring assembly 112 includes one or more annular members. In one embodiment, the one or more annular members include one or more edge rings and at least one cover ring. The edge ring is made of an electrically conductive material or an insulating material, and the cover ring is made of an insulating material.

The substrate support 11 may include a temperature control module configured to adjust the temperature of at least one of the electrostatic chuck 114, the ring assembly 112, and the substrate W to a target temperature. The temperature control module may include a heater, a heat transfer medium, a flow path 120, or a combination thereof. A heat transfer fluid, such as brine or gas, flows through the flow path 120. In one embodiment, the flow path 120 is formed in the base 113, and one or more heaters are disposed in the chuck main body 200 of the electrostatic chuck 114. The substrate support 11 may include a heat transfer gas supply configured to supply the heat transfer gas to a gap between the rear surface of the substrate W and the substrate support surface 111a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the gas introduction ports 13c. The shower head 13 further includes at least one upper electrode. The gas introduction unit may include, in addition to the shower head 13, one or a plurality of side gas injectors (SGI) that are attached to one or a plurality of openings formed in the sidewall 10a.

The gas supply 20 may include at least one gas source 21 and at least one flow rate controller 22. In one embodiment, the gas supply 20 is configured to supply at least one processing gas from the respective corresponding gas sources 21 to the shower head 13 via the respective corresponding flow rate controllers 22. The flow rate controller 22 may include, for example, a mass flow controller or a pressure-controlled flow rate controller. Further, the gas supply 20 may include at least one flow rate modulation device that modulates or pulses the flow rate of at least one processing gas.

The power source 30 includes the RF power source 31 coupled to the plasma processing chamber 10 via at least one impedance matching circuit. The RF power source 31 is configured to supply at least one RF signal (RF power) to at least one lower electrode and/or at least one upper electrode. Plasma is thus generated from the at least one processing gas supplied into the plasma processing space 10s. Accordingly, the RF power source 31 may function as at least a part of the plasma generator 12. Supplying the bias RF signal to at least one lower electrode can generate a bias potential in the substrate W to attract an ionic component in the formed plasma to the substrate W.

In one embodiment, the RF power source 31 includes a first RF generator 31a and a second RF generator 31b. The first RF generator 31a is coupled to at least one lower electrode and/or at least one upper electrode via at least one impedance matching circuit, and is configured to generate a source RF signal (source RF power) for plasma generation. In one embodiment, the source RF signal has a frequency within a range from 10 MHz to 150 MHz. In one embodiment, the first RF generator 31a may be configured to generate a plurality of source RF signals having different frequencies. The generated one or more source RF signals are supplied to at least one lower electrode and/or at least one upper electrode.

The second RF generator 31b is configured to be coupled to at least one lower electrode via at least one impedance matching circuit to generate a bias RF signal (bias RF power). A frequency of the bias RF signal may be the same as or different from a frequency of the source RF signal. In one embodiment, the bias RF signal has a frequency lower than the frequency of the source RF signal. In one embodiment, the bias RF signal has a frequency within a range from 100 kHz to 60 MHz. In one embodiment, the second RF generator 31b may be configured to generate a plurality of bias RF signals having different frequencies. The generated one or more bias RF signals are supplied to at least one lower electrode. In various embodiments, at least one of the source RF signal and the bias RF signal may be pulsed.

The power source 30 may include the DC power source 32 coupled to the plasma processing chamber 10. The DC power source 32 includes a first DC generator 32a and a second DC generator 32b. In one embodiment, the first DC generator 32a is connected to at least one lower electrode to generate a first DC signal. The generated first DC signal is applied to at least one lower electrode. In one embodiment, the second DC generator 32b is connected to at least one upper electrode and configured to generate a second DC signal. The generated second DC signal is applied to the at least one upper electrode.

In various embodiments, the first and second DC signals may be pulsed. In this case, a sequence of voltage pulses is applied to at least one lower electrode and/or at least one upper electrode. The voltage pulses may each have a rectangular, trapezoidal, or triangular pulse waveform or a combination thereof. In one embodiment, a waveform generator that generates the sequence of the voltage pulses from a DC signal is connected between the first DC generator 32a and at least one lower electrode. Accordingly, the first DC generator 32a and the waveform generator form a voltage pulse generator. When the second DC generator 32b and the waveform generator form a voltage pulse generator, the voltage pulse generator is connected to at least one upper electrode. The voltage pulse may have a positive polarity or a negative polarity. Further, the sequence of the voltage pulses may include one or more positive voltage pulses and one or more negative voltage pulses in one cycle. The first and second DC generators 32a and 32b may be provided in addition to the RF power source 31, and the first DC generator 32a may be provided instead of the second RF generator 31b.

The exhaust system 40 may be connected, for example, to a gas discharge port 10e disposed at a bottom portion of the plasma processing chamber 10. The exhaust system 40 may include a pressure adjusting valve and a vacuum pump. The pressure adjusting valve adjusts a pressure in the plasma processing space 10s. The vacuum pump may include a turbo molecular pump, a dry pump, or a combination thereof.

### Plasma Processing Method

Next, plasma processing performed using the plasma processing system configured as described above will be described. As the plasma processing, for example, etching processing or film formation processing is performed (herein “film” means the same as “layer”).

First, the substrate W is loaded into the plasma processing chamber 10, and the substrate W is placed on the electrostatic chuck 114. Thereafter, by applying a DC voltage to the electrostatic electrode 201 of the electrostatic chuck 114, the substrate W is electrostatically attracted and held on the electrostatic chuck 114 by a coulomb force. At this time, the substrate W is adjusted to a desired temperature. Further, after the substrate W is carried in, the pressure inside the plasma processing chamber 10 is reduced to a desired vacuum level by the exhaust system 40.

Next, a processing gas is supplied from the gas supply 20 to the plasma processing space 10s through the shower head 13. Further, the first RF generator 31a of the RF power source 31 supplies the source RF power for plasma generation to the conductive member of the substrate support 11 and/or the conductive member of the shower head 13. Then, the processing gas is excited to generate the plasma. At this time, the second RF generator 31b may supply a bias RF signal for attracting ions. Then, the generated plasma acts to subject the substrate W to the plasma processing.

### First Embodimen

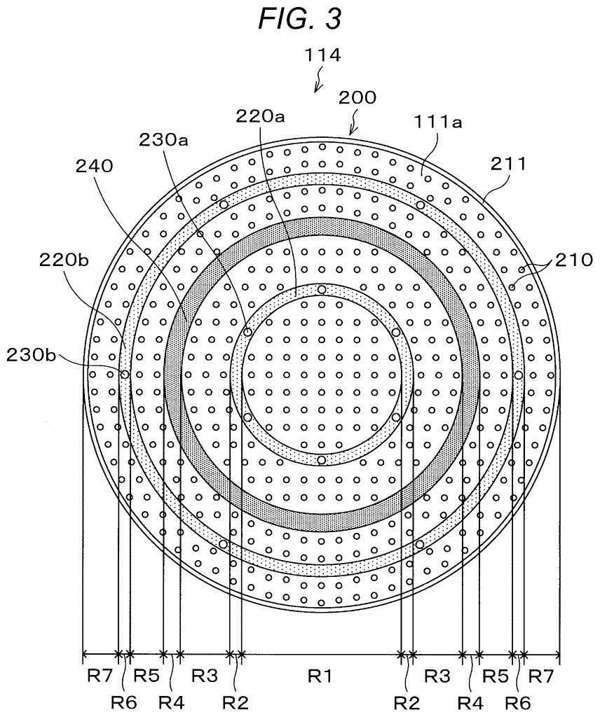

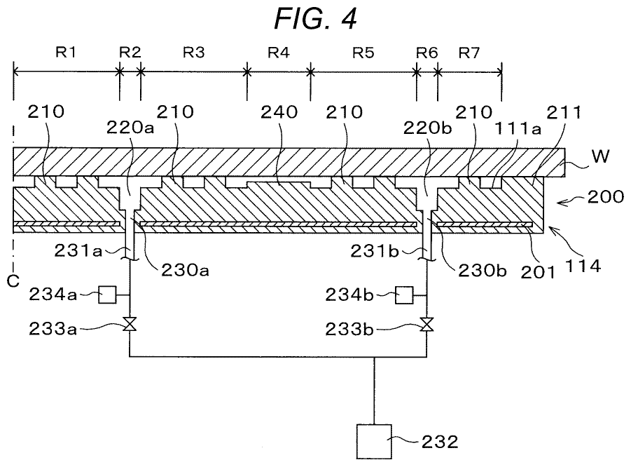

Next, the configuration of the electrostatic chuck 114 according to a first embodiment will be described. FIG. 3 is a plan view illustrating a schematic configuration of the electrostatic chuck 114. FIG. 4 is a vertical sectional view illustrating the schematic configuration of the electrostatic chuck 114. In FIG. 4, C indicates a center line of the electrostatic chuck 114.

As illustrated in FIGS. 3 and 4, the electrostatic chuck 114 includes the chuck main body 200. The chuck main body 200 is formed of a dielectric and is formed of, for example, ceramic such as alumina (Al₂O₃). The electrostatic chuck 114 has a substantially disc shape. For example, the electrostatic electrode 201 connected to the first DC generator 32a is provided in the chuck main body 200. By applying a direct-current voltage from the first DC generator 32a to the electrostatic electrode 201 to generate a coulomb force, the electrostatic chuck 114 can attract the substrate W. A heater may be provided in the chuck main body 200.

An upper surface of the chuck main body 200 has the substrate support surface 111a for supporting the substrate W. The substrate support surface 111a is formed in, for example, a circle having a diameter less than that of the substrate W to be supported. Accordingly, when the substrate W is supported on the substrate support surface 111a, an outer peripheral portion of the substrate W protrudes outward from an end of the substrate support surface 111a.

The substrate support surface 111a of the chuck main body 200 includes substrate contact portions 210 serving as protrusions and an outer peripheral contact portion 211 serving as an outer peripheral protrusion. The substrate contact portion 210 is a dot having a columnar shape and is provided to protrude from the substrate support surface 111a. The substrate contact portions 210 are provided inside the outer peripheral contact portion 211. The outer peripheral contact portion 211 is provided in an annular shape protruding from the substrate support surface 111a at an outermost peripheral portion of the substrate support surface 111a. That is, the outer peripheral contact portion 211 surrounds a first annular groove 220a, a second annular groove 220b, and an annular projection 240, which will be described later. The substrate contact portions 210 and the outer peripheral contact portion 211 are formed to have flat upper surfaces at the same height, and come into contact with the substrate W when the substrate W is supported by the electrostatic chuck 114. Therefore, the substrate W is supported by the substrate contact portions 210 and the outer peripheral contact portion 211.

At least one annular groove 220, two annular grooves 220a and 220b in the present embodiment, are formed in the substrate support surface 111a of the chuck main body 200. The annular grooves 220a and 220b are each recessed from the substrate support surface 111a and formed in an annular shape, and in the present embodiment, in a circular shape. The annular grooves 220a and 220b are disposed side by side in this order from the inside to the outside in a radial direction, and the second annular groove 220b is disposed to surround the first annular groove 220a. Central positions of the annular grooves 220a and 220b in a plan view are the same as a central position of the substrate support surface 111a. That is, the annular grooves 220a and 220b are disposed concentrically.

The annular grooves 220a and 220b each have a rectangular shape in a cross-sectional view. The annular grooves 220a and 220b have the same cross-sectional shape. In the following description, the annular grooves 220a and 220b may be collectively referred to as the annular grooves 220.

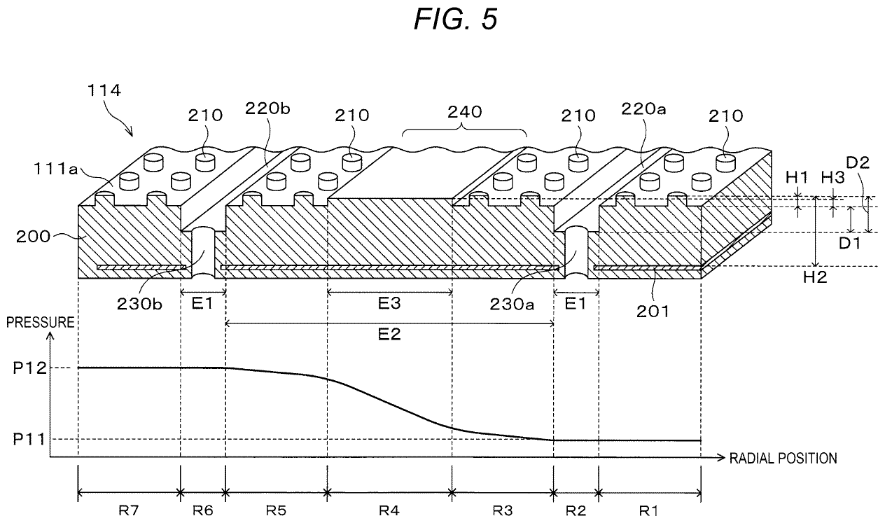

As illustrated in FIG. 5, a depth D1 (a depth from the substrate support surface 111a to a bottom of the annular groove 220) of the annular groove 220 is equal to or larger than a height H1 (a height from the substrate support surface 111a to an upper surface of the substrate contact portion 210) of the substrate contact portion 210. A depth D2 (a depth from the upper surface of the substrate contact portion 210 to the bottom of the annular groove 220) of the annular groove 220 is twice or more the height H1 of the substrate contact portion 210. For example, the height H1 of the substrate contact portion 210 is 5 μm to 20 μm, and the depth D2 of the annular groove 220 is 10 μm to 40 μm.

Upper limit values of the depths D1 and D2 of the annular groove 220 are not particularly limited. For example, the annular groove 220 may extend vertically downward until the bottom thereof is located slightly above the upper surface of the electrostatic electrode 201 without reaching the electrostatic electrode 201. For example, the depth D1 of the annular groove 220 may be half or less of a distance H2 from the upper surface of the substrate contact portion 210 to the upper surface of the electrostatic electrode 201.

A width E1 (radial length) of the annular groove 220 is, for example, 0.3 mm to 10 mm. The width E1 of the annular groove 220 is also not particularly limited.

As illustrated in FIGS. 3 and 4, first heat transfer gas supply holes 230a serving as at least one first gas supply hole are formed in the first annular groove 220a. The first heat transfer gas supply hole 230a is formed penetrating the chuck main body 200 from a bottom of the first annular groove 220a. A first heat transfer gas supply path 231a serving as at least one first gas supply path is connected to the first heat transfer gas supply hole 230a, and the first heat transfer gas supply path 231a communicates with a heat transfer gas source 232. The first heat transfer gas supply path 231a is provided with at least one first control valve 233a and a first pressure gauge 234a from a side of the heat transfer gas source 232. An opening degree of the first control valve 233a is controlled such that the pressure detected by the first pressure gauge 234a becomes a desired pressure. Accordingly, the first control valve 233a is configured to control a flow rate or pressure of the heat transfer gas supplied from the heat transfer gas source 232 via the first heat transfer gas supply path 231a. The first control valve 233a and the first pressure gauge 234a may be integrally provided. The heat transfer gas supplied from the heat transfer gas source 232 is supplied to the first annular groove 220a through the first heat transfer gas supply path 231a and the first heat transfer gas supply hole 230a, and diffuses in a circumferential direction along the first annular groove 220a. The heat transfer gas is also supplied to a space (hereinafter, referred to as a “heat transfer space”) between the rear surface of the substrate W and the substrate support surface 111a.

Second heat transfer gas supply holes 230b serving as at least one second gas supply hole are formed in the second annular groove 220b. The second heat transfer gas supply hole 230b is formed penetrating the chuck main body 200 from a bottom of the second annular groove 220b. A second heat transfer gas supply path 231b serving as at least one second gas supply path is connected to the second heat transfer gas supply hole 230b, and the second heat transfer gas supply path 231b communicates with the heat transfer gas source 232. The second heat transfer gas supply path 231b is provided with at least one second control valve 233b and a second pressure gauge 234b from the side of the heat transfer gas source 232. The second control valve 233b and the second pressure gauge 234b have the same configurations as the first control valve 233a and the first pressure gauge 234a, respectively, and the second control valve 233b is configured to control the flow rate or the pressure of the heat transfer gas. Similar to the first annular groove 220a, the heat transfer gas supplied from the heat transfer gas source 232 through the second heat transfer gas supply path 231b and the second heat transfer gas supply hole 230b diffuses in the circumferential direction along the second annular groove 220b and is also supplied to the heat transfer space.

In the present embodiment, the heat transfer gas supply paths 231a and 231b merge and communicate with the common heat transfer gas source 232, and may communicate with individual heat transfer gas sources, respectively. In the present embodiment, the flow rate or the pressures of the heat transfer gas supplied from the heat transfer gas supply holes 230a and 230b are controlled by using the control valves 233a and 233b, and in addition thereto, the flow rate or the pressures of the heat transfer gas may be controlled by changing diameters of the heat transfer gas supply holes 230a and 230b. As the heat transfer gas (backside gas), for example, a helium gas is used. In the following description, the heat transfer gas supply holes 230a and 230b may be collectively referred to as a heat transfer gas supply hole 230, the heat transfer gas supply paths 231a and 231b may be collectively referred to as a heat transfer gas supply path 231, the control valves 233a and 233b may be collectively referred to as a control valve 233, and the pressure gauges 234a and 234b may be collectively referred to as a pressure gauge 234.

As illustrated in FIGS. 3 to 5, the annular projection 240 functioning as a pressure adjustment portion is formed on the substrate support surface 111a of the chuck main body 200 as described later. The annular projection 240 protrudes from the substrate support surface 111a and is formed in an annular shape, and in the present embodiment, a circular shape. The annular projection 240 is disposed between the first annular groove 220a and the second annular groove 220b. A central position of the annular projection 240 in the plan view is the same as the central position of the substrate support surface 111a. That is, the annular grooves 220a and 220b and the annular projection 240 are disposed concentrically. The annular projection 240 is disposed at a radial central position between the first annular groove 220a and the second annular groove 220b.

The annular projection 240 has a rectangular shape in a cross-sectional view. The annular projection 240 does not come in contact with the substrate W supported by the substrate contact portion 210 of the electrostatic chuck 114. That is, as illustrated in FIG. 5, a height H3 of the annular projection 240 (a height from the substrate support surface 111a to an upper surface of the annular projection 240) is smaller than the height H1 of the substrate contact portion 210 (the height from the substrate support surface 111a to the upper surface of the substrate contact portion 210). The height H3 of the annular projection 240 is larger than half the height H1 of the substrate contact portion 210. Accordingly, the height H3 of the annular projection 240 is set to a range satisfying Expression (1) below. For example, the height H1 of the substrate contact portion 210 is 5 μm to 20 μm, and the height H3 of the annular projection 240 is 2.5 μm to 10 μm.

(H1)/2<(H3)<(H1) (1)

A width E3 (radial length) of the annular projection 240 is smaller than one-third of the radial distance E2 between the first annular groove 220a and the second annular groove 220b. The width E3 of the annular projection 240 is larger than 0.3 mm. Therefore, the width E3 of the annular projection 240 is set to a range satisfying Expression (2) below. For example, the radial distance E2 between the annular groove 220a and the annular groove 220b is 15 mm to 90 mm, and the width E3 of the annular projection 240 is 5 mm to 30 mm.

0.3 mm<(E3)<(E2)/3 (2)

A material for the annular projection 240 is, for example, the same as that of the chuck main body 200. However, the material for the annular projection 240 is not particularly limited. Regardless of the material for the annular projection 240, the annular projection 240 can achieve an effect of pressure control in a heat transfer space to be described later.

The annular grooves 220a and 220b and the annular projection 240 partition the substrate support surface 111a into seven regions R1 to R7. The first region R1 is a circular region inside the first annular groove 220a in the radial direction. The second region R2 is an annular region in which the first annular groove 220a is formed. The third region R3 is an annular region between the first annular groove 220a and the annular projection 240. The fourth region R4 is an annular region in which the annular projection 240 is formed. The fifth region R5 is an annular region between the annular projection 240 and the second annular groove 220b. The sixth region R6 is an annular region in which the second annular groove 220b is formed. The seventh region R7 is an annular region between the second annular groove 220b and the outer peripheral contact portion 211. The substrate contact portions 210 described above are disposed in each of the regions R1, R3, R5, and R7.

For example, when the pressures of the heat transfer gases supplied from the heat transfer gas supply holes 230a and 230b are different from each other, the pressure of the heat transfer space is controlled for each of the seven regions R1 to R7. FIG. 5 is a view illustrating a pressure distribution of the heat transfer spaces in the regions R1 to R7 when a pressure P12 of a heat transfer gas from the second heat transfer gas supply hole 230b (the second annular groove 220b) is higher than a pressure P11 from the first heat transfer gas supply hole 230a (the first annular groove 220a). In a graph of FIG. 5, a vertical axis indicates the pressure in the heat transfer space, and a horizontal axis indicates a radial position of the substrate W in a specific direction.

The heat transfer gas from the first heat transfer gas supply hole 230a diffuses into the heat transfer spaces inside the first annular groove 220a in the radial direction, that is, the heat transfer spaces in the first region R1 and the second region R2. The pressures in the heat transfer spaces in the first region R1 and the second region R2 are substantially the same as the pressure P11 of a heat transfer gas from the first heat transfer gas supply hole 230a.

The heat transfer gas from the second heat transfer gas supply hole 230b diffuses into the heat transfer spaces outside the second annular groove 220b in the radial direction, that is, the heat transfer spaces in the sixth region R6 and the seventh region R7. The pressures in the heat transfer spaces in the sixth region R6 and the seventh region R7 are substantially the same as the pressure P12 of the heat transfer gas from the second heat transfer gas supply hole 230b.

As described above, the heat transfer gas diffuses in the circumferential direction along the first annular groove 220a, and the heat transfer gas diffuses in the circumferential direction along the second annular groove 220b. Between the heat transfer spaces between the first annular groove 220a and the second annular groove 220b, that is, between the heat transfer spaces in the regions R3 to R5 and the heat transfer spaces in the regions R1 and R2 inside in the radial direction, gas conductance in the heat transfer space decreases, and a differential pressure is generated. Similarly, between the heat transfer spaces in the regions R3 to R5 and the heat transfer spaces in the regions R6 and R7 outside in the radial direction, the gas conductance in the heat transfer space decreases, and a differential pressure is generated. That is, the pressures in the heat transfer spaces in the regions R3 to R5 change from P11 to P12 from an inside toward an outside in the radial direction.

The annular projection 240 is formed in the fourth region R4, and a radial change of the pressure (hereinafter referred to as a “pressure gradient”) in the heat transfer space is increased by the annular projection 240. That is, in the regions R3 to R5 from the outside toward the inside in the radial direction, a pressure gradient is small in the heat transfer space in the fifth region R5, a pressure gradient is large in the heat transfer space in the fourth region R4, and a pressure gradient is small in the heat transfer space in the third region R3.

As described above, according to the present embodiment, it is possible to generate a differential pressure between the heat transfer spaces in the regions R3 to R5 and the heat transfer spaces in the regions R1 and R2, and to generate a differential pressure between the heat transfer spaces in the regions R3 to R5 and the heat transfer spaces in the regions R6 and R7. As a result, the pressure in the heat transfer space of each of the regions R1 to R7 can be controlled, thereby controlling the temperature of the substrate W for each of the regions R1 to R7. At this time, since the differential pressure can be generated without coming into contact with the substrate W by forming the annular grooves 220a and 220b and the annular projection 240, a local temperature singularity that occurs when the seal band comes into contact with the substrate as in the related art does not occur. Therefore, according to the present embodiment, temperature controllability of the substrate W can be improved, and the uniformity of the plasma processing in the substrate surface can be improved.

As described above, according to the present embodiment, when the substrate support surface 111a is partitioned into the regions R1 to R7, since the electrostatic chuck 114 does not come into contact with the substrate W, the seal band is not worn out and changes in shape as in the seal band in the related art. Therefore, a temporal change is unlikely to occur, and the pressures in the heat transfer spaces in the regions R1 to R7 can be appropriately controlled.

Here, when the annular projection 240 is not formed in the regions R3 to R5, the pressures in the heat transfer spaces in the regions R3 to R5 have a constant pressure gradient from the outside toward the inside in the radial direction. In this respect, according to the present embodiment, since the annular projection 240 is formed in the fourth region R4 in the regions R3 to R5, a flow of the heat transfer gas can be changed in the annular projection 240, and the pressure gradient in the heat transfer space in the fourth region R4 can be increased. That is, a steep pressure change can be provided in the fourth region R4. Therefore, a pressure distribution in the radial direction in the heat transfer space can be controlled more precisely. As a result, the temperature controllability of the substrate W can be further improved, and the uniformity of the plasma processing in the substrate surface can be further improved.

In the regions R3 to R5, since there is no need to form the annular groove 220 similar to the annular grooves 220a and 220b, a supply system such as the heat transfer gas supply path 231, the control valve 233, and the pressure gauge 234 for supplying the heat transfer gas to the annular groove 220 becomes unnecessary. Therefore, the temperature controllability of the substrate W can be improved with a simple structure in which the annular projection 240 is formed.

Further, according to the present embodiment, since the heat transfer gas diffuses along the circumferential direction in the annular grooves 220a and 220b, it is also possible to improve the temperature uniformity of the substrate W in the circumferential direction.

According to the present embodiment, since the outer peripheral contact portion 211 that comes into contact with the substrate W is provided at the outermost peripheral portion of the substrate support surface 111a, it is possible to prevent the heat transfer gas from flowing out of the heat transfer space even when the heat transfer gas is supplied to the heat transfer space inside the outer peripheral contact portion 211 in the radial direction.

In the above-described embodiment illustrated in FIGS. 3 to 5, the annular projection 240 is disposed at the radially central position between the first annular groove 220a and the second annular groove 220b. However, a position of the annular projection 240 is not limited thereto. The position of the annular projection 240 is freely set according to a required pressure gradient, that is, a temperature gradient.

In the above-described embodiment illustrated in FIGS. 3 to 5, a case where two annular grooves 220a and 220b and one annular projection 240 are formed on the substrate support surface 111a of the chuck main body 200 has been described. However, the number and a disposition of the annular grooves 220 and the annular projection 240 are not limited thereto.

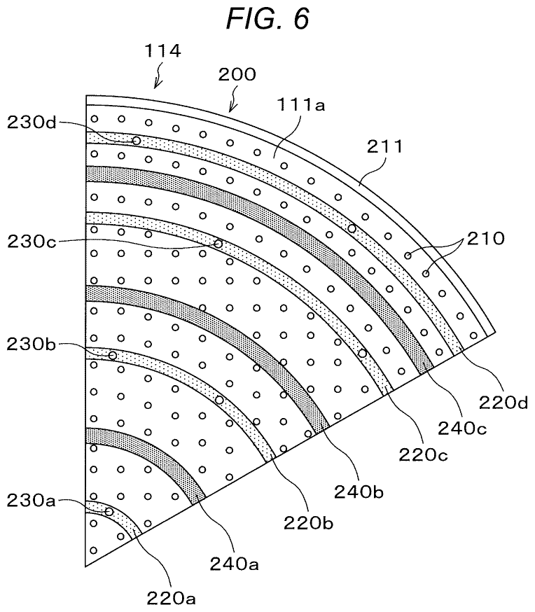

As an example, as illustrated in FIG. 6, the substrate support surface 111a may have four annular grooves 220a, 220b, 220c, and 220d and three annular projections 240a, 240b, and 240c. The annular grooves 220a, 220b, 220c, and 220d and the annular projections 240a, 240b, and 240c are concentrically disposed.

The annular grooves 220a, 220b, 220c, and 220d are disposed side by side in this order from the inside to the outside in the radial direction. Heat transfer gas supply holes 230a, 230b, 230c, and 230d are formed in the annular grooves 220a, 220b, 220c, and 220d, respectively, and further, heat transfer gas supply paths 231a, 231b, 231c, and 231d are connected to the annular grooves 220a, 220b, 220c, and 220d, respectively. The heat transfer gas supply paths 231a, 231b, 231c, and 231d are provided with control valves 233a, 233b, 233c, and 233d, and pressure gauges 234a, 234b, 234c, and 234d, respectively.

A first annular projection 240a is disposed between the first annular groove 220a and the second annular groove 220b. A second annular projection 240b is disposed between the second annular groove 220b and a third annular groove 220c. A third annular projection 240c is disposed between the third annular groove 220c and a fourth annular groove 220d. As described above, the height H3 of each of the annular projections 240a, 240b, and 240c satisfies Expression (1) below with respect to the height H1 of the substrate contact portion 210. The width E3 of each of the annular projections 240a, 240b, and 240c satisfies Expression (2) below with respect to the radial distance E2 between the annular grooves 220.

(H1)/2<(H3)<(H1) (1)

0.3 mm<(E3)<(E2)/3 (2)

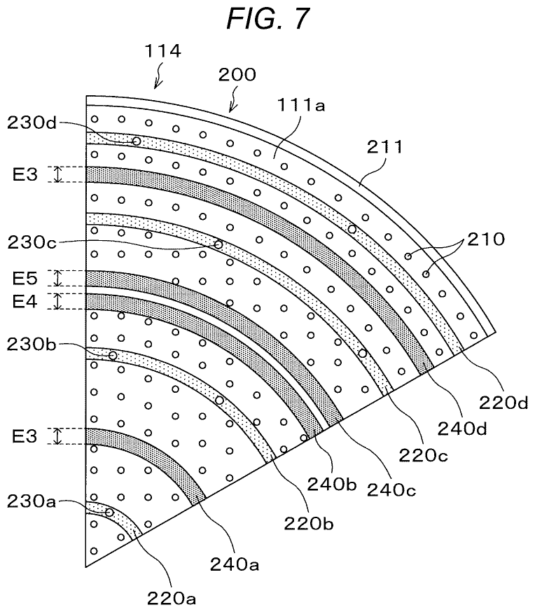

As another example, as illustrated in FIG. 7, the substrate support surface 111a may have the four annular grooves 220a, 220b, 220c, and 220d and four annular projections 240a, 240b, 240c, and 240d. In the example illustrated in FIG. 7, a plurality of, for example, the second annular projection 240b and the third annular projection 240c are disposed between the second annular groove 220b and the third annular groove 220c in the example illustrated in FIG. 6.

As described above, the height H3 of each of the annular projections 240a, 240b, 240c, and 240d satisfies Expression (1) below with respect to the height H1 of the substrate contact portion 210. The width E3 of the first annular projection 240a and a fourth annular projection 240d satisfies Expression (2) below with respect to the radial distance E2 between the annular grooves 220. Meanwhile, a sum of a width E4 of the second annular projection 240b and a width E5 of the third annular projection 240c satisfies Expression (2) below, that is, Expression (2′) below. Even when the annular projections 240b and 240c are provided between the annular grooves 220b and 220c in this way, the effects described above can be achieved as long as the widths E4 and E5 of the annular projections 240b and 240c satisfy Expression (2′) below, and a pressure in a heat transfer space between the annular grooves 220b and 220c can be appropriately controlled.

(H1)/2<(H3)<(H1) (1)

0.3 mm<(E3)<(E2)/3 (2)

0.3 mm<(E3)=(E4+E5)<(E2)/3 (2′)

Simulations related to the present embodiment will now be described. In this simulation, a model illustrated in FIG. 6, i.e., a model in which the annular grooves 220a, 220b, 220c, and 220d and the annular projections 240a, 240b, and 240c are formed on the substrate support surface 111a, was used as an example. As a comparative example, in the example illustrated in FIG. 6, a model was used in which only the annular grooves 220a, 220b, 220c, and 220d were formed on the substrate support surface 111a, and the annular projections 240a, 240b, and 240c were not formed on the substrate support surface 111a.

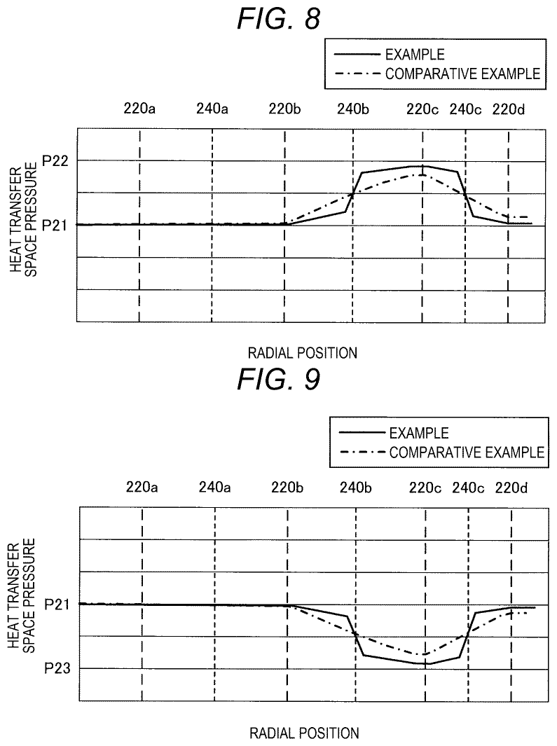

FIG. 8 is a view illustrating a pressure in a heat transfer space on the substrate W when a pressure P22 of a heat transfer gas in the third annular groove 220c is higher than a pressure P21 of a heat transfer gas in the other annular grooves 220a, 220b, and 220d in this simulation. In a graph of FIG. 8, a vertical axis indicates the pressure in the heat transfer space, and a horizontal axis indicates a radial position of the substrate W in a specific direction.

Referring to FIG. 8, in a comparative example, a pressure gradient in a heat transfer space is substantially constant between the annular grooves 220b and 220c, and a pressure gradient in a heat transfer space is substantially constant between the annular grooves 220c and 220d. Therefore, it was not possible to properly control the pressure gradient in the heat transfer space in regions of these annular grooves 220b to 220d.

Meanwhile, in the example, a pressure gradient in a heat transfer space is small between the second annular groove 220b and the second annular projection 240b and between the third annular groove 220c and the second annular projection 240b, whereas a pressure gradient in a heat transfer space is large in the second annular projection 240b. Therefore, a steep pressure change could be provided in the second annular projection 240b.

Similarly, in the example, a pressure gradient in a heat transfer space is small between the third annular groove 220c and the third annular projection 240c and between the fourth annular groove 220d and the third annular projection 240c, whereas a pressure gradient in a heat transfer space is large in the third annular projection 240c. Therefore, a steep pressure change could be provided in the third annular projection 240c.

In the example, a maximum value of the pressure in the heat transfer space in the third annular groove 220c is larger than that in the comparative example. This is because forming the second annular projection 240b and the third annular projection 240c makes it easier to apply a differential pressure to an entire region of the annular grooves 220b to 220d, and thus increases a pressures of a high pressure and a low pressure. From this viewpoint as well, in the example, the pressure in the heat transfer space can be appropriately controlled.

FIG. 9 is a view illustrating a pressure in a heat transfer space on the substrate W when a pressure P23 of a heat transfer gas in the third annular groove 220c is lower than the pressure P21 of the heat transfer gas in the other annular grooves 220a, 220b, and 220d in this simulation. Even in this case, similar results as those illustrated in FIG. 8 were obtained.

That is, with reference to FIG. 9, in a comparative example, a pressure gradient in a heat transfer space is substantially constant between the annular grooves 220b and 220c, and a pressure gradient in a heat transfer space is substantially constant between the annular grooves 220c and 220d. Therefore, it was not possible to sharply control the pressure gradient in the heat transfer space in regions of these annular grooves 220b to 220d.

Meanwhile, in the example, the pressure gradient in the heat transfer space is small between the second annular groove 220b and the second annular projection 240b and between the third annular groove 220c and the second annular projection 240b, whereas the pressure gradient in the heat transfer space is large in the second annular projection 240b. Therefore, a steep pressure change could be provided in the second annular projection 240b.

Similarly, in the example, a pressure gradient in a heat transfer space is small between the third annular groove 220c and the third annular projection 240c and between the fourth annular groove 220d and the third annular projection 240c, whereas a pressure gradient in a heat transfer space is large in the third annular projection 240c. Therefore, a steep pressure change could be provided in the third annular projection 240c.

As described above, results of the simulation have also illustrated that effects of the present embodiment can be achieved. That is, according to the present embodiment, it is possible to control the pressure in the heat transfer space according to a position of the annular projection 240 in both a case where the annular projection 240 is formed on a high-pressure side and a case where the annular projection 240 is formed on a low-pressure side.

A pressure gradient in a heat transfer space in a region where the annular projection 240 is formed can be controlled by the height H3 and the width E3 of the annular projection 240.

For example, when the height H3 of the annular projection 240 is large, the pressure gradient in the heat transfer space in the annular projection 240 becomes large. Since the annular projection 240 is formed so as not to be in contact with the substrate W, the height H3 of the annular projection 240 is smaller than the height H1 of the substrate contact portion 210 as illustrated in Expression (1) below.

Meanwhile, when the height H3 of the annular projection 240 is small, the pressure gradient in the heat transfer space in the annular projection 240 becomes small. In this respect, when the simulation was performed while changing the height H3 of the annular projection 240, it was found that when the height H3 of the annular projection 240 is larger than half the height H1 of the substrate contact portion 210 as illustrated in Expression (1) below, the effect of the annular projection 240 described above, i.e., an effect of being able to control the pressure gradient in the heat transfer space of the annular projection 240 to be sufficiently large, can be achieved.

(H1)/2<(H3)<(H1) (1)

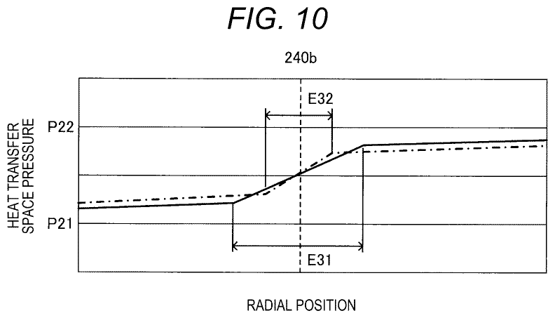

FIG. 10 is a view illustrating a pressure distribution of the heat transfer space in the second annular projection 240b when the width E3 of the second annular projection 240b is varied between a width E31 and a width E32 in the simulation illustrated in FIG. 8.

Referring to FIG. 10, when the width E3 of the second annular projection 240b is large and is the width E31, a pressure gradient in the heat transfer space in the second annular projection 240b becomes small. A region where a pressure changes becomes large. In this respect, it has been found that when the width E31 (width E3) of the second annular projection 240b is smaller than one-third of the radial distance E2 between the annular grooves 220 as illustrated in Expression (2) below, the effect of the second annular projection 240b described above, i.e., an effect of being able to control a pressure gradient in a heat transfer space of the second annular projection 240b to be sufficiently large, can be achieved.

Meanwhile, when the width E3 of the second annular projection 240b is small and is the width E32, a pressure gradient of a heat transfer space in the second annular projection 240b becomes large. A region where the pressure changes becomes small. In this respect, it has been found that the effect of the second annular projection 240b described above can be achieved when the width E32 (width E3) of the second annular projection 240b is larger than 0.3 mm, as illustrated in Expression (2) below.

0.3 mm<(E3)<(E2)/3 (2)

A pressure gradient in the heat transfer space in the annular projection 240 is determined according to specifications preferred for the substrate W. The height H3 of the annular projection 240 is determined in the range satisfying Expression (1), and the width E3 of the annular projection 240 is determined in the range satisfying Expression (2).

### Modification of First Embodiment

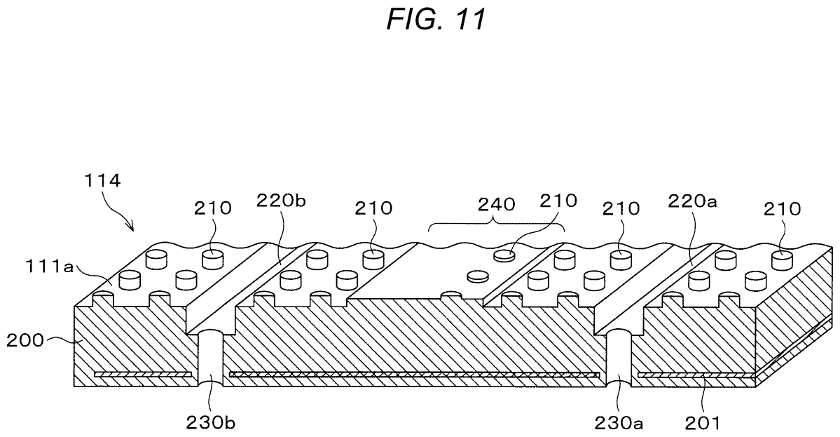

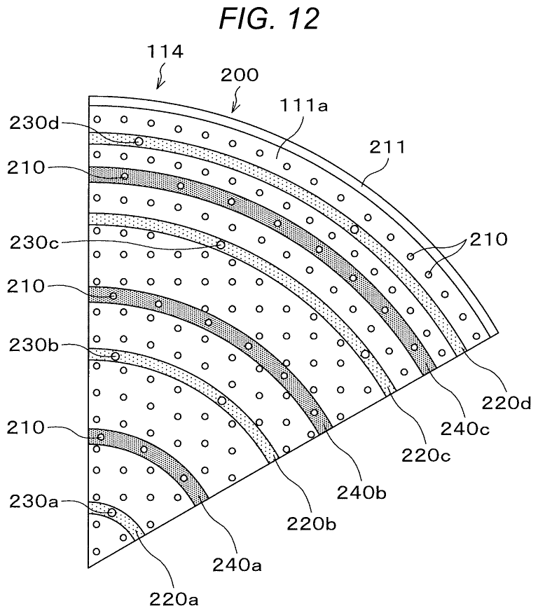

For example, in the electrostatic chuck 114 illustrated in FIG. 6, the plurality of substrate contact portions 210 may be provided on the upper surface of the annular projection 240 as illustrated in FIGS. 11 and 12. Simulations were performed to compare a case where the substrate contact portion 210 was provided on the upper surface of the annular projection 240 and a case where the substrate contact portion 210 was not provided. The pressure gradients in the heat transfer space in the annular projection 240 were substantially the same. When the substrate contact portion 210 is provided on the upper surface of the annular projection 240 in this way, for example, even when the width E3 of the annular projection 240 is large, the substrate W can be appropriately supported by the substrate contact portion 210.

### Second Embodiment

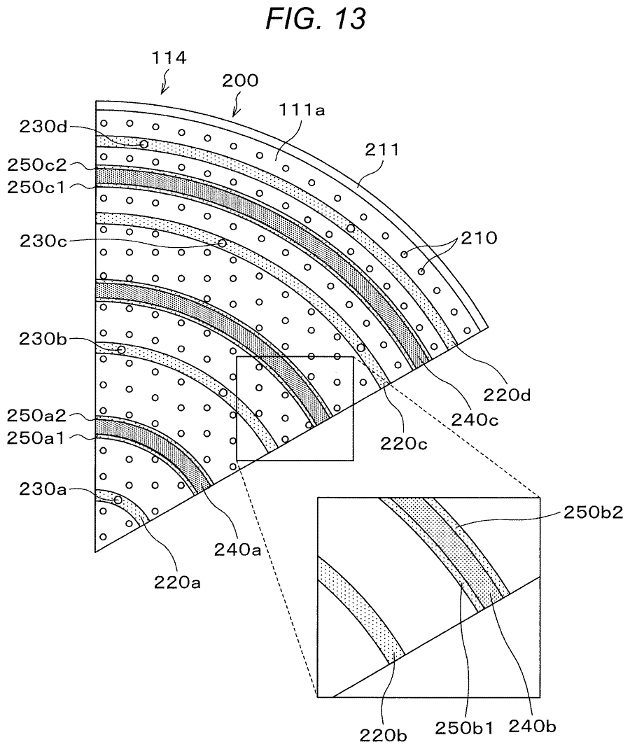

Next, a configuration of the electrostatic chuck 114 according to a second embodiment will be described. In the second embodiment, as illustrated in FIG. 13, an annular adjacent groove 250 adjacent to the annular projection 240 is formed on the substrate support surface 111a.

For example, in the electrostatic chuck 114 illustrated in FIG. 6, a first inner adjacent groove 250a1 is formed radially inward of the first annular projection 240a, and a first outer adjacent groove 250a2 is formed radially outward of the first annular projection 240a. Similarly, inner adjacent grooves 250b1 and 250c1 and outer adjacent grooves 250b2 and 250c2 are formed radially inward and outward of the annular projections 240b and 240c respectively. In the following description, the adjacent grooves 250a1, 250a2, 250b1, 250b2, 250c1, and 250c2 may be collectively referred to as the adjacent groove 250.

A depth of the adjacent groove 250 (a depth from the substrate support surface 111a to a bottom of the adjacent groove 250) is, for example, the same as the depth D1 of the annular groove 220. A width (radial length) of the adjacent groove 250 is not particularly limited, and is, for example, 0.5 mm. In this case, it is possible to improve controllability of the pressure in the heat transfer space by the annular projection 240.

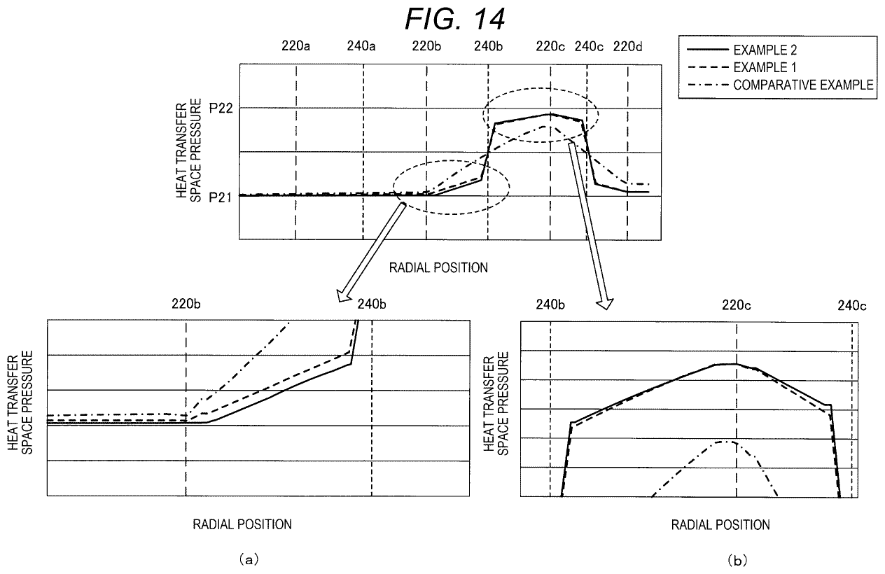

FIG. 14 is a view illustrating a pressure in the heat transfer space on the substrate W when the pressure P22 of the heat transfer gas in the third annular groove 220c is higher than the pressure P21 of the heat transfer gas in the other annular grooves 220a, 220b, and 220d in the simulation using a model illustrated in FIG. 13. That is, pressure conditions of the heat transfer gas in this simulation are the same as pressure conditions of the heat transfer space in the simulation illustrated in FIG. 8 (simulation using the model illustrated in FIG. 6). In the following description, a simulation using the model illustrated in FIG. 6 will be referred to as Example 1, and a simulation using the model illustrated in FIG. 13 of the present example will be referred to as Example 2. Similar to the simulation illustrated in FIG. 8, a comparative example is a simulation using a model in which, in the example illustrated in FIG. 6, only the annular grooves 220a, 220b, 220c, and 220d were formed on the substrate support surface 111a, and the annular projections 240a, 240b, and 240c were not formed on the substrate support surface 111a.

Referring to FIG. 14, as illustrated in (a) of FIG. 14, a pressure gradient in a heat transfer space in Example 2 is smaller than that in Example 1 on a radially inner side of the second annular projection 240b. In other words, the second inner adjacent groove 250b1 increases a heat transfer gradient in the heat transfer space in the second annular projection 240b. As illustrated in (b) of FIG. 14, a pressure gradient in a heat transfer space in Example 2 is smaller than that in Example 1 on a radially outside of the second annular projection 240b. In other words, the second outer adjacent groove 250b2 increases the heat transfer gradient in the heat transfer space in the second annular projection 240b. As described above, the adjacent grooves 250b1 and 250b2 can improve controllability of a pressure in the heat transfer space in the second annular projection 240b.

Here, when a pressure in a heat transfer space is controlled using the seal band that comes into contact with the back surface of the substrate as in the related art, the heat transfer spaces are spaced apart radially inward and outward of the seal band, and thus, a pressure change in the heat transfer space in the seal band has a rectangular shape. In this respect, when the adjacent groove 250 is adjacent to the annular projection 240 as in the present embodiment, the pressure change in the heat transfer space approaches the rectangular shape as illustrated in FIG. 14. From this viewpoint as well, it can be found that controllability of the pressure in the heat transfer space in the annular projection 240 can be improved by the adjacent groove 250.

When the annular adjacent groove 250 adjacent to the annular projection 240 is formed, the heat transfer gas diffuses along the circumferential direction in the adjacent groove 250, so that uniformity of a pressure in the circumferential direction of the heat transfer space can also be improved.

In order to achieve an effect of improving the controllability of the pressure by the adjacent groove 250, the depth of the adjacent groove 250 may be larger than the depth D1 of the annular groove 220. In order to achieve the effect, it is preferable that an aspect ratio of the adjacent groove 250 be large.

In the above-described embodiment, the adjacent grooves 250 are formed radially inward and outward of all the annular projections 240. However, the number of the adjacent grooves 250 is not limited thereto. For example, the adjacent groove 250 may be formed either radially inward or outward of the annular projection 240. For example, the adjacent groove 250 may be adjacent to any of the annular projections 240.

### Third Embodiment

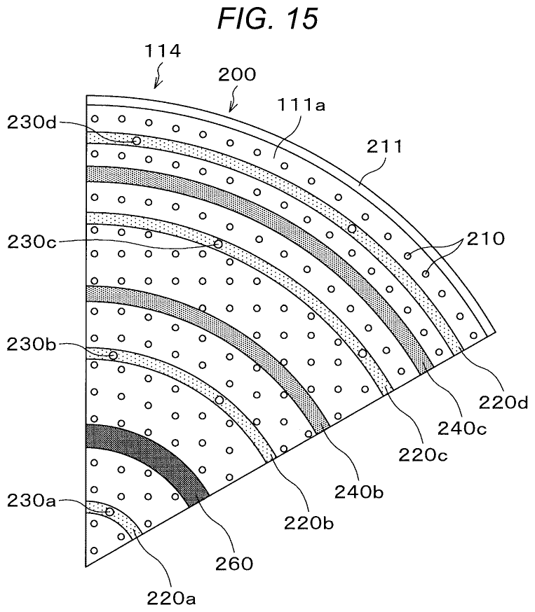

Next, a configuration of the electrostatic chuck 114 according to a third embodiment will be described. In the third embodiment, as illustrated in FIG. 15, an intermediate groove 260 functioning as a pressure adjustment groove is formed on the substrate support surface 111a.

For example, in the electrostatic chuck 114 illustrated in FIG. 6, the intermediate groove 260 is formed instead of the first annular projection 240a. That is, the intermediate groove 260, the second annular projection 240b, the third annular projection 240c, and the annular grooves 220a, 220b, 220c, and 220d are formed on the substrate support surface 111a.

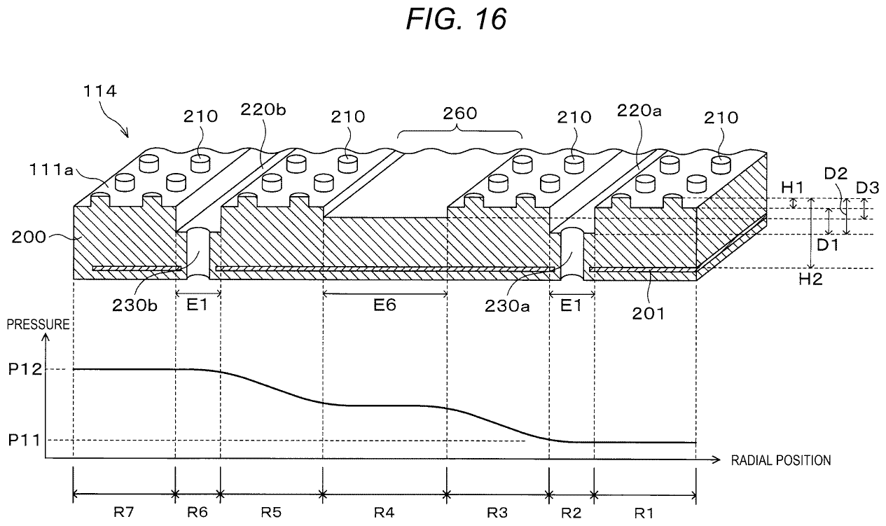

The intermediate groove 260 is recessed from the substrate support surface 111a and formed in an annular shape, and in the present embodiment, in a circular shape. The intermediate groove 260 has a rectangular shape in a cross-sectional view. As illustrated in FIG. 16, a depth D3 (a depth from the upper surface of the substrate contact portion 210 to a bottom of the intermediate groove 260) of the intermediate groove 260 is less than the depth D2 (the depth from the upper surface of the substrate contact portion 210 to the bottom of the annular groove 220) of the annular groove 220. For example, the height H1 of the substrate contact portion 210 is 5 μm to 20 μm, and the depth D3 of the intermediate groove 260 is 10 μm to 30 μm.

A width E6 of the intermediate groove 260 is equal to or larger than the width E1 of the annular groove 220. For example, the width E6 of the intermediate groove 260 is 10 mm to 50 mm. The width E6 of the intermediate groove 260 is not particularly limited.

Seven regions R1 to R7 in FIG. 16 are similar to the seven regions R1 to R7 illustrated in FIG. 5. The fourth region R4 is an annular region in which the intermediate groove 260 is formed. The graph of FIG. 16 is a similar graph as the graph illustrated in FIG. 5, and represents pressures of heat transfer spaces in the regions R1 to R7 when the pressure P12 of the heat transfer gas from the second heat transfer gas supply hole 230b is larger than the pressure P11 from the first heat transfer gas supply hole 230a.

The pressures in the heat transfer spaces in the first region R1 and the second region R2 are substantially the same as the pressure P11 of the heat transfer gas from the first heat transfer gas supply hole 230a. Similarly, the pressures in the heat transfer spaces in the sixth region R6 and the seventh region R7 are substantially the same as the pressure P12 of the heat transfer gas from the second heat transfer gas supply hole 230b. That is, the pressures in the heat transfer spaces in the regions R3 to R5 change from P11 to P12 from the inside toward the outside in the radial direction.

The intermediate groove 260 is formed in the fourth region R4, and the pressure gradient in the heat transfer space is small or substantially constant by the intermediate groove 260. That is, in the regions R3 to R5 from the outside toward the inside in the radial direction, the pressure gradient is large in the heat transfer space in the fifth region R5, the pressure gradient is small in the heat transfer space in the fourth region R4, and the pressure gradient is large in the heat transfer space in the third region R3.

As described above, according to the present embodiment, since the intermediate groove 260 is formed in the fourth region R4 in the regions R3 to R5, a flow of the heat transfer gas can be changed in the intermediate groove 260, and the pressure gradient of the heat transfer space in the fourth region R4 can be reduced. Therefore, a pressure distribution in the radial direction in the heat transfer space can be controlled more precisely. As a result, the temperature controllability of the substrate W can be further improved, and the uniformity of the plasma processing in the substrate surface can be further improved.

The pressure gradient of the heat transfer space in the fourth region R4 can be controlled by the depth D3 of the intermediate groove 260. For example, when the depth D3 of the intermediate groove 260 is large, the pressure gradient of the heat transfer space in the fourth region R4 is small. Meanwhile, for example, when the depth D3 of the intermediate groove 260 is small, the pressure gradient of the heat transfer space in the fourth region R4 is large. The pressure gradient of the heat transfer space in the fourth region R4 is determined and the depth D3 of the intermediate groove 260 is determined according to specifications preferred for the substrate W.

It has been found that when the depth D3 of the intermediate groove 260 is about half the depth D2 of the annular groove 220 as in the present embodiment, the effect of the intermediate groove 260 described above, that is, an effect of being able to control the pressure gradient of the heat transfer space in the fourth region R4 to be sufficiently small, can be exhibited.

In the present embodiment, the depth D3 of the intermediate groove 260 is less than the depth D2 of the annular groove 220. However, the depth D3 of the intermediate groove 260 and the depth D2 of the annular groove 220 may be the same. Even in this case, the effect described above, that is, the effect of being able to control the pressure gradient of the heat transfer space in the fourth region R4, can be achieved. An upper limit value of the depth D3 of the intermediate groove 260 is not particularly limited, and is preferably set to an extent that abnormal discharge can be prevented because there is a concern that the abnormal discharge may occur when the depth D3 is excessively large.

The pressure gradient of the heat transfer space in the fourth region R4 is also affected by the width E6 of the intermediate groove 260. For example, when the width E6 of the intermediate groove 260 is small, the pressure gradient of the heat transfer space in the fourth region R4 is large. Meanwhile, for example, when the width E6 of the intermediate groove 260 is large, the pressure gradient of the heat transfer space in the fourth region R4 is small.

In the embodiment described above, the intermediate groove 260 is formed instead of the first annular projection 240a. However, the number and a disposition of the intermediate grooves 260 are not limited thereto. For example, the intermediate groove 260 may be formed in place of either or both of the second annular projection 240b and the third annular projection 240c. For example, a plurality of intermediate grooves 260 may be formed between the annular grooves 220.

### Fourth Embodiment

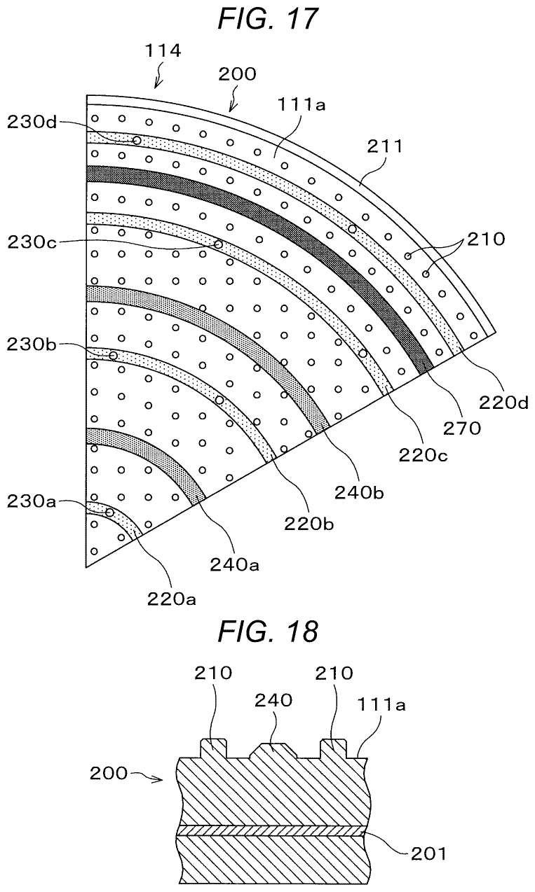

Next, a configuration of the electrostatic chuck 114 according to the fourth embodiment will be described. In the fourth embodiment, as illustrated in FIG. 17, a seal band 270 is formed on the substrate support surface 111a.

For example, in the electrostatic chuck 114 illustrated in FIG. 6, the seal band 270 is formed instead of the third annular projection 240c. That is, the seal band 270, the first annular projection 240a, the second annular projection 240b, and the annular grooves 220a, 220b, 220c, and 220d are formed on the substrate support surface 111a.

The seal band 270 is provided in an annular shape, protruding from the substrate support surface 111a. An upper surface of the seal band 270 is flat, and comes into contact with the substrate W when the substrate W is supported by the electrostatic chuck 114.

Accordingly, since the heat transfer spaces are spaced apart radially inward and outward of the seal band 270, the pressure gradient in the heat transfer space can be increased by the seal band 270, so that a steeper pressure change can be provided. Therefore, for example, the seal band 270 is useful when it is desired to particularly improve the controllability of the pressure in the heat transfer space.

In the embodiment described above, the seal band 270 is formed instead of the third annular projection 240c. However, the number and a disposition of the seal bands 270 are not limited thereto. For example, the seal band 270 may be formed in place of either or both of the first annular projection 240a or the second annular projection 240b.

### Fifth Embodiment

The first to fourth embodiments described above may be combined. That is, in addition to the annular projection 240, at least one of the adjacent groove 250, the intermediate groove 260, and the seal band 270 may be formed on the substrate support surface 111a. These combinations can be freely set according to pressure control preferred for a process performed in the plasma processing apparatus 1.

### Sixth Embodiment

In the embodiment described above, the annular projection 240 has a rectangular shape in a cross-sectional view and is formed in a circular shape in a plan view. However, the shape of the annular projection 240 is not limited thereto.

For example, as illustrated in FIG. 18, the annular projection 240 may have a trapezoidal shape that tapers downward from the upper side in a cross-sectional view. For example, as illustrated in FIG. 19, the annular projection 240 may have a semicircular shape that is curved upward in a cross-sectional view.

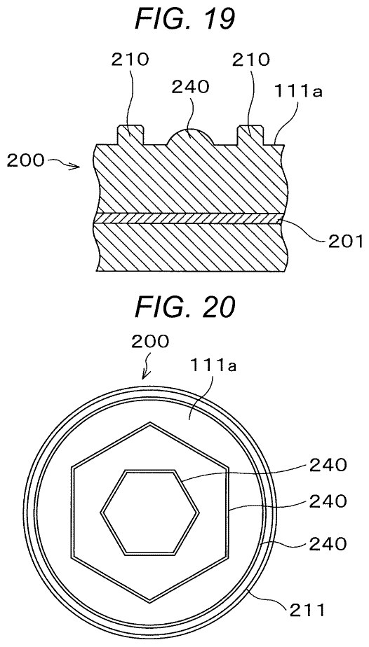

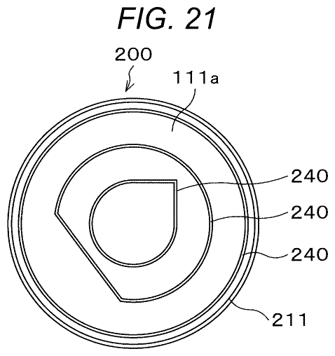

For example, as illustrated in FIG. 20, the annular projection 240 may have a polygonal shape, for example, a hexagonal shape in a plan view. For example, as illustrated in FIG. 21, the annular projection 240 may have another planar shape, instead of a circular shape, in a plan view. Further, the annular projections 240 have different central positions in a plan view, and may have a central asymmetric shape.

The annular projection 240 has a continuous annular shape in a plan view. However, a part of the annular projection 240 may be discontinuous. At this time, the annular projection 240 may be discontinuous at one location, or may be discontinuous at a plurality of locations. In this way, the annular projection 240 may include a plurality of segments divided in the circumferential direction, and the annular projection 240 may be formed in an annular shape as a whole.

As described above, regardless of the shape of the annular projection 240, a similar effect as in the above-described embodiment can be achieved, i.e., the pressure gradient in the heat transfer space in the annular projection 240 can be controlled.

According to the present disclosure, the temperature of the substrate can be appropriately controlled to improve the uniformity of the plasma processing in the substrate surface.

It shall be understood that the embodiments disclosed herein are illustrative and are not restrictive in all aspects. The embodiment described above may be omitted, replaced, or modified in various forms without departing from the scope and spirit of the appended claims. For example, the components of the embodiments described above may be combined as desired. From the desired combination, functions and effects of each component related to the combination can be obtained as a matter of course, and other functions and effects apparent to those skilled in the art can be obtained from the description herein.

The effects described herein are merely illustrative or exemplary, and are not limited. In other words, the technique according to the present disclosure may have other effects apparent to those skilled in the art from the description herein, in addition to or in place of the effects described above.

Reference to an element in the singular is not intended to mean “one and only one” unless explicitly so stated, but rather “one or more.” Moreover, where a phrase similar to “at least one of A, B, or C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A and B and C.

No claim element herein is to be construed under the provisions of 35 U.S.C. 112(f) unless the element is expressly recited using the phrase “means for.” As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

The scope of the invention is indicated by the appended claims, rather than the foregoing description.

The following configuration examples also fall within the technical scope of the present disclosure.

(1)

A substrate processing apparatus including:
a substrate processing chamber, a substrate support disposed in the substrate processing chamber and having at least one first gas supply path and at least one second gas supply path, the substrate support including a base and an electrostatic chuck that is disposed on the base and has an upper surface, protrusions, a first annular groove, a second annular groove surrounding the first annular groove, and an annular projection disposed between the first annular groove and the second annular groove, protruding from the upper surface, and lower than the protrusions, being formed on the upper surface, the first annular groove communicating with the at least one first gas supply path via at least one first gas supply hole, and the second annular groove communicating with the at least one second gas supply path via at least one second gas supply hole, at least one first control valve configured to control a flow rate or a pressure of a gas supplied via the at least one first gas supply path, and at least one second control valve configured to control a flow rate or a pressure of a gas supplied via the at least one second gas supply path.
   (2)

The substrate processing apparatus according to (1), in which a height of the annular projection is larger than half a height of each of the protrusions.

(3)

The substrate processing apparatus according to (1) or (2), in which a width of the annular projection is smaller than one-third of a radial distance between the first annular groove and the second annular groove.

(4)

The substrate processing apparatus according to any one of (1) to (3), in which a plurality of the annular projections are disposed between the first annular groove and the second annular groove.

(5)

The substrate processing apparatus according to any one of (1) to (4), in which the protrusions are provided in the annular projection.

(6)

The substrate processing apparatus according to any one of (1) to (5), in which an annular adjacent groove adjacent to the annular projection is formed on at least one of a radially inner side and a radially outer side of the annular projection on the upper surface.

(7)

The substrate processing apparatus according to any one of (1) to (6), in which an annular intermediate groove disposed between the first annular groove and the second annular groove and shallower than the first annular groove and the second annular groove is formed on the upper surface.

(8)

The substrate processing apparatus according to any one of (1) to (8), in which the upper surface has an annular outer peripheral protrusion that surrounds the first annular groove and the second annular groove.

(9)

An electrostatic chuck including:

an upper surface, and a chuck main body having at least one first gas supply path and at least one second gas supply path, in which protrusions, a first annular groove, a second annular groove surrounding the first annular groove, and an annular projection disposed between the first annular groove and the second annular groove, protruding from the upper surface, and lower than the protrusions are formed on the upper surface, the first annular groove communicates with the at least one first gas supply path via at least one first gas supply hole, and the second annular groove communicates with the at least one second gas supply path via at least one second gas supply hole.

(10)

The electrostatic chuck according to (9), in which a height of the annular projection is larger than half a height of each of the protrusions.

(11)

The electrostatic chuck according to (9) or (10), in which a width of the annular projection is smaller than one-third of a radial distance between the first annular groove and the second annular groove.

(12)

The electrostatic chuck according to any one of (9) to (11), in which a plurality of the annular projections are disposed between the first annular groove and the second annular groove.

(13)

The electrostatic chuck according to any one of (9) to (12), in which the protrusions are provided in the annular projection.

(14)

The electrostatic chuck according to any one of (9) to (13), in which an annular adjacent groove adjacent to the annular projection is formed on at least one of a radially inner side and a radially outer side of the annular projection on the upper surface.

(15)

The electrostatic chuck according to any one of (9) to (14), in which an annular intermediate groove disposed between the first annular groove and the second annular groove and shallower than the first annular groove and the second annular groove is formed on the upper surface.

(16)

The electrostatic chuck according to any one of (9) to (15), in which the upper surface has an annular outer peripheral protrusion that surrounds the first annular groove and the second annular groove.

1. A substrate processing apparatus comprising:
a substrate processing chamber,
a substrate support disposed in the substrate processing chamber and having at least one first gas supply path and at least one second gas supply path,
the substrate support including a base and an electrostatic chuck that is disposed on the base and has an upper surface,
protrusions, a first annular groove, a second annular groove surrounding the first annular groove, and an annular projection disposed between the first annular groove and the second annular groove, protruding from the upper surface, and lower than the protrusions, being located on the upper surface,
the first annular groove communicates with the at least one first gas supply path via at least one first gas supply hole, and
the second annular groove communicates with the at least one second gas supply path via at least one second gas supply hole,
at least one first control valve to control a flow rate or a pressure of a gas supplied via the at least one first gas supply path, and
at least one second control valve to control a flow rate or a pressure of a gas supplied via the at least one second gas supply path.

2. The substrate processing apparatus according to claim 1, wherein a height of the annular projection is larger than half a height of each of the protrusions.

3. The substrate processing apparatus according to claim 1, wherein
a width of the annular projection is smaller than one-third of a radial distance between the first annular groove and the second annular groove.

4. The substrate processing apparatus according to claim 1, wherein
a plurality of the annular projections are disposed between the first annular groove and the second annular groove.

5. The substrate processing apparatus according to claim 1, wherein
the protrusions are provided in the annular projection.

6. The substrate processing apparatus according to claim 1, wherein
an annular adjacent groove adjacent to the annular projection is located on at least one of a radially inner side and a radially outer side of the annular projection on the upper surface.

7. The substrate processing apparatus according to claim 1, wherein
an annular intermediate groove disposed between the first annular groove and the second annular groove and shallower than the first annular groove and the second annular groove is located on the upper surface.

8. The substrate processing apparatus according to claim 1, wherein
the upper surface has an annular outer peripheral protrusion that surrounds the first annular groove and the second annular groove.

9. An electrostatic chuck comprising:
an upper surface, and
a chuck main body having at least one first gas supply path and at least one second gas supply path, wherein
protrusions, a first annular groove, a second annular groove surrounding the first annular groove, and an annular projection disposed between the first annular groove and the second annular groove, protruding from the upper surface, and lower than the protrusions are located on the upper surface,
the first annular groove communicates with the at least one first gas supply path via at least one first gas supply hole, and
the second annular groove communicates with the at least one second gas supply path via at least one second gas supply hole.

10. The electrostatic chuck according to claim 9, wherein
a height of the annular projection is larger than half a height of each of the protrusions.

11. The electrostatic chuck according to claim 9, wherein
a width of the annular projection is smaller than one-third of a radial distance between the first annular groove and the second annular groove.

12. The electrostatic chuck according to claim 9, wherein
a plurality of the annular projections are disposed between the first annular groove and the second annular groove.

13. The electrostatic chuck according to claim 9, wherein the protrusions are provided in the annular projection.

14. The electrostatic chuck according to claim 9, wherein
an annular adjacent groove adjacent to the annular projection is located on at least one of a radially inner side and a radially outer side of the annular projection on the upper surface.

15. The electrostatic chuck according to claim 9, wherein
an annular intermediate groove disposed between the first annular groove and the second annular groove and shallower than the first annular groove and the second annular groove is located on the upper surface.

16. The electrostatic chuck according to claim 9, wherein
the upper surface has an annular outer peripheral protrusion that surrounds the first annular groove and the second annular groove.

17. A substrate processing apparatus comprising:
a substrate processing chamber,
a substrate support disposed in the substrate processing chamber and having at least one first gas supply path and at least one second gas supply path,
the substrate support including a base and an electrostatic chuck that is disposed on the base and has an upper surface,
protrusions, a first annular groove, a second annular groove surrounding the first annular groove, and an annular projection disposed between the first annular groove and the second annular groove, protruding from the upper surface, and lower than the protrusions, being located on the upper surface, wherein a height of the annular projection is larger than half a height of each of the protrusions and a width of the annular projection is smaller than one-third of a radial distance between the first annular groove and the second annular groove,
the first annular groove communicates with the at least one first gas supply path via at least one first gas supply hole, and
the second annular groove communicates with the at least one second gas supply path via at least one second gas supply hole,
at least one first control valve to control a flow rate or a pressure of a gas supplied via the at least one first gas supply path, and
at least one second control valve to control a flow rate or a pressure of a gas supplied via the at least one second gas supply path.

18. The substrate processing apparatus according to claim 17, wherein
a plurality of the annular projections are disposed between the first annular groove and the second annular groove.

19. The substrate processing apparatus according to claim 17, wherein the protrusions are provided in the annular projection.

20. The substrate processing apparatus according to claim 17, wherein
an annular adjacent groove adjacent to the annular projection is located on at least one of a radially inner side and a radially outer side of the annular projection on the upper surface.
